(19) United States
(12) Patent Application Publication
(10) Pub. No.: US 2015/0357356 A1
(43) Pub. Date: Dec. 10, 2015

(54) THIN FILM TRANSISTOR ARRAY SUBSTRATE AND METHOD OF MANUFACTURING THE SAME

(71) Applicant: Samsung Display Co., Ltd., Yongin-City (KR)

(72) Inventors: Jae-Neung KIM, Yongin-City (KR); Yu-Gwang JEONG, Yongin-City (KR); Su-Bin BAE, Yongin-City (KR); Yun-Jong YEO, Yongin-City (KR)

(21) Appl. No.: 14/621,303

(22) Filed: Feb. 12, 2015

(30) Foreign Application Priority Data
Jun. 10, 2014 (KR) 10-2014-0070270

(51) Int. Cl. H01L 27/12; H01L 29/66; H01L 29/786

(52) U.S. Cl. CPC H01L 27/1288; H01L 27/1214; H01L 27/1225; H01L 29/7869; H01L 29/78669; H01L 29/66969; H01L 29/66765

(57) ABSTRACT

A thin film transistor array substrate and a method of manufacturing the thin film transistor array substrate are provided. The thin film transistor array substrate includes: a substrate; a gate electrode disposed on the substrate; a gate insulating layer disposed on the gate electrode; a semiconductor pattern disposed on the gate insulating layer; a source electrode and a drain electrode disposed on the semiconductor pattern and spaced apart from each other; and a hard mask pattern disposed on the source electrode and the drain electrode.

### RELATED APPLICATION

This application claims the benefit of Korean Patent Application No. 10-2014-0070270 filed on Jun. 10, 2014 in the Korean Intellectual Property Office, the disclosure of which is incorporated herein in its entirety by reference.

### BACKGROUND

1. Technical Field

The present disclosure relates to a thin film transistor array substrate and a method of manufacturing the same.

2. Description of the Related Art

A flat panel display apparatus (such as an organic light emitting display apparatus or a liquid crystal display (LCD) apparatus) typically includes thin film transistors (TFTs), capacitors, and wiring connecting the TFTs and the capacitors formed on a substrate.

The wiring may include minute patterns formed using a photolithography method (whereby patterns are transferred using a mask).

The photolithography method may include the following operations. First, the substrate (on which patterns are to be formed) is coated uniformly with a photoresist. Next, the photoresist is exposed using an exposure apparatus (such as a stepper), and the photosensitized photoresist is then developed. After developing the photoresist, patterns are etched onto the substrate using the remaining photoresist as a mask. Lastly, the remaining photoresist is removed after the patterns have been formed on the substrate.

However, in some instances, one or more TFTs may be damaged due to semiconductor materials in the TFTs being inadvertently removed during the etching step.

### SUMMARY

The present disclosure addresses at least the above issues relating to damage of thin film transistors (TFTs) during manufacture of a flat panel display apparatus.

According to one or more embodiments of the inventive concept, a thin film transistor array substrate includes: a substrate: a gate electrode disposed on the substrate; a gate insulating layer disposed on the gate electrode; a semiconductor pattern disposed on the gate insulating layer; a source electrode and a drain electrode disposed on the semiconductor pattern and spaced apart from each other; and a hard mask pattern disposed on the source electrode and the drain electrode.

In one embodiment, the hard mask pattern may have a same area as a top surface of the source electrode and a top surface of the drain electrode.

In one embodiment, the hard mask pattern may be formed of an insulating material.

In one embodiment, the hard mask pattern may have a stack structure comprising a first hard mask pattern and a second hard mask pattern, wherein the first hard mask pattern and the second hard mask pattern may be formed of different materials.

In one embodiment, the hard mask pattern may include a contact hole exposing at least one of the source electrode and the drain electrode.

In one embodiment, the thin film transistor array substrate may further include: an ohmic contact layer disposed between the semiconductor pattern and the source electrode and between the semiconductor layer and the drain electrode, wherein the semiconductor pattern may include amorphous silicon (a-Si).

In one embodiment, the semiconductor pattern may include an oxide semiconductor.

In one embodiment, the thin film transistor array substrate may further include: a data line disposed on the substrate and spaced apart from the gate electrode, wherein the gate insulating layer may be disposed covering the data line, and wherein the data line may be electrically connected to the drain electrode.

In one embodiment, the thin film transistor array substrate may further include: a protection layer covering the hard mask pattern, the source electrode, the semiconductor pattern, and the drain electrode.

In one embodiment, the thin film transistor array substrate may further include: a pixel electrode connected to the source electrode; and a planarization layer disposed between the source electrode and the pixel electrode.

In one embodiment, the planarization layer may include an organic material.

In one embodiment, the thin film transistor array substrate may further include: an intermediate layer disposed on the pixel electrode, wherein the intermediate layer may include an organic emission layer or a liquid crystal layer; and an opposite electrode disposed on the intermediate layer.

According to one or more embodiments of the inventive concept, a method of manufacturing a thin film transistor array substrate includes: forming a gate electrode and a data line on a substrate, wherein the substrate includes a thin film transistor region; sequentially forming a gate insulating layer, a semiconductor pattern including a channel region, and a source-drain layer on the substrate covering the gate electrode and the data line; forming a preliminary first hard mask pattern on the source-drain layer in the thin film transistor region; forming a second hard mask pattern on the preliminary first hard mask pattern, wherein the second hard mask pattern includes a second opening disposed corresponding to the channel region; etching the source-drain layer by using the preliminary first hard mask pattern as a first etching mask; forming a first hard mask pattern by using the second hard mask pattern as a second etching mask, wherein the first hard mask pattern includes a first opening disposed corresponding to the channel region; and forming a source electrode and a drain electrode by etching the source-drain layer using the first hard mask pattern as a third etching mask.

In one embodiment, the preliminary first hard mask pattern and the second hard mask pattern may be formed through a halftone mask process.

In one embodiment, forming the second hard mask pattern may further include: forming a second hard mask layer on the source-drain layer; forming a photoresist using a halftone mask, wherein the photoresist may include a first part and a second part, and wherein a thickness of the second part may be less than a thickness of the first part; etching the source-drain layer by using the photoresist as a fourth etching mask; exposing a portion of the second hard mask layer corresponding to the channel region by etching the second part of the photoresist; and etching the exposed portion of the second hard mask layer by using the first part of the photoresist as a fifth etching mask, wherein the first part of the photoresist may be formed in a region in which the source electrode and the drain electrode are to be formed, and the second part of the photoresist may be disposed corresponding to the channel region.

In one embodiment, the first hard mask pattern and the second hard mask pattern may be formed of different insulating materials.

In one embodiment, the method may further include: removing the second hard mask pattern.

In one embodiment, the method may further include: forming a planarization layer over the substrate covering the source electrode, the drain electrode, and the data line.

In one embodiment, the method may further include: forming a pixel electrode and a connection wiring on the planarization layer, wherein the pixel electrode may be connected to the source electrode and the connection wiring may be connected to the drain electrode.

### BRIEF DESCRIPTION OF THE DRAWINGS

The above and/or other aspects of the inventive concept will be apparent in light of the following description of the different embodiments and the accompanying drawings.

FIG. 1 is a cross-sectional view of a thin film transistor array substrate according to an embodiment of the inventive concept.

FIG. 2 is a cross-sectional view of a thin film transistor array substrate according to another embodiment of the inventive concept.

FIGS. 3A, 3B, 3C, 3D, 3E, 3F, 3G, 3H, 3I, and 3J are cross-sectional views sequentially illustrating a thin film transistor array substrate at different stages of fabrication according to an exemplary method of manufacturing the thin film transistor array substrate.

FIG. 4 is a cross-sectional view of an organic light emitting display apparatus including the thin film transistor array substrate of FIG. 1.

FIG. 5 is a cross-sectional view of a liquid crystal display (LCD) apparatus including the thin film transistor array substrate of FIG. 1.

### DETAILED DESCRIPTION

Reference will now be made in detail to embodiments of the inventive concept, examples of which are illustrated in the accompanying drawings. As used herein, the term “and/or” includes any and all combinations of one or more of the associated listed items. Expressions such as “at least one of,” when preceding a list of elements, modify the entire list of elements and do not modify the individual elements of the list.

While the inventive concept is amenable to various modifications and alternative forms, specific embodiments have been shown by way of example in the drawings and are described in detail below. Effects and features of the inventive concept and implementation methods thereof will be described using the following embodiments with reference to the accompanying drawings. The inventive concept may, however, be embodied in different forms and should not be construed as being limited to the embodiments described herein.

Like reference numerals in the drawings denote like elements, and thus a repeated description of those same elements will be omitted.

It will be understood that although the terms “first”, “second”, etc. may be used herein to describe various components, the components should not be limited by those terms. Instead, those terms are merely used to distinguish one component from another.

As used herein, the singular forms “a”, “an”, and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. That is, for example, intervening layers, regions, or components may be present.

Sizes of elements in the drawings may be exaggerated in the interest of clarity.

A specific process order may be performed differently from the described order in different embodiments. For example, two sequentially described processes may be performed substantially at the same time or performed in an order opposite to the described order.

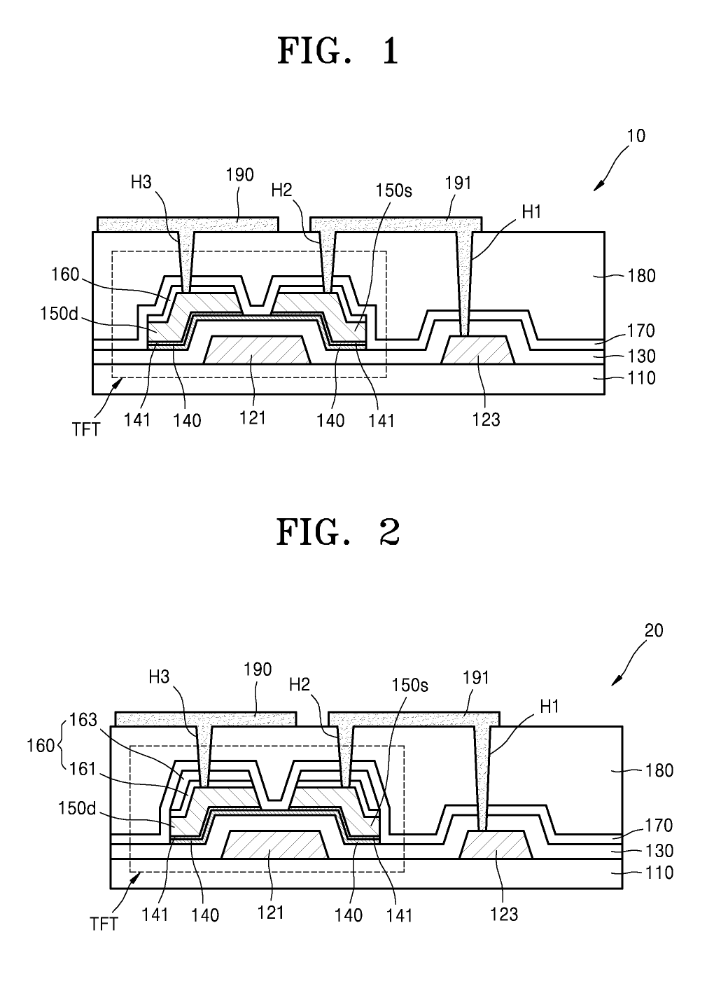

FIG. 1 is a cross-sectional view of a thin film transistor array substrate 10 according to an embodiment of the inventive concept.

Referring to FIG. 1, the thin film transistor array substrate 10 may include a substrate 110, a thin film transistor TFT, a data line 123, a planarizing layer 180, a pixel electrode 190, and a connection wiring 191.

In the interest of clarity, only a single thin film transistor is illustrated in FIG. 1. However, it should be noted that the inventive concept is not limited thereto, and may include a plurality of thin film transistors. For example, in the thin film transistor array substrate 10 according to the present embodiment, a plurality of thin film transistors may be arranged on the substrate 110 in a regular pattern, and a gate line (not shown) connected to a gate electrode 121 and a data line 123 may be provided so as to enable the plurality of thin film transistors to individually operate.

The substrate 110 may be formed of a glass material, a plastic material, or a metal material. The substrate 110 may be a flexible substrate.

A buffer layer (not shown) may be formed on the substrate 110. The buffer layer provides a flat surface to a top portion of the substrate 110. The buffer layer may include an insulating material that prevents moisture and impurities from penetrating into the substrate 110. In some alternative embodiments, the buffer layer may be omitted.

The thin film transistor TFT may be formed on the substrate 110. The thin film transistor TFT may include the gate electrode 121, a gate insulating layer 130 disposed on the gate electrode 121, a semiconductor pattern 140 disposed on the gate insulating layer 130, a source electrode 150s and a drain electrode 150d disposed on the semiconductor pattern 140, and a hard mask pattern 160 disposed on the source electrode 150s and the drain electrode 150d.

The gate electrode 121 and the data line 123 may be formed of a same material and may be formed simultaneously. In some embodiments, the gate electrode 121 and the data line 123 may be formed of aluminum (Al), an aluminum alloy, tungsten (W), copper (Cu), nickel (Ni), chromium (Cr), molybdenum (Mo), titanium (Ti), platinum (Pt), tantalum (Ta), or a combination thereof. In some embodiments, the gate electrode 121 and the data line 123 may be formed in a stack structure comprising Ti/Cu, Mo/Al/Mo, or Ti/Al/Ti.

The gate insulating layer 130 is disposed covering the gate electrode 121 and the data line 123, and includes a connection contact hole H1 exposing a part of the data line 123. The gate insulating layer 130 may be formed of an insulating material, and may electrically insulate the gate electrode 121 from the semiconductor pattern 140. In some embodiments, the gate insulating layer 130 may be formed of an inorganic material or an organic material. In some embodiments, the gate insulating layer 130 may be formed in a single-layer structure or a stack structure. In some embodiments, the gate insulating layer 130 may include silicon nitride and/or silicon oxide.

The semiconductor pattern 140 is formed on the gate insulating layer 130 and overlaps at least a part of the gate electrode 121.

In some embodiments, the semiconductor pattern 140 may be formed of amorphous silicon (a-Si). In those embodiments, an ohmic contact layer 141 may be further formed between the semiconductor pattern 140 and the source electrode 150s and between the semiconductor pattern 140 and the drain electrode 150d. The ohmic contact layer 141 serves to reduce contact resistance between the semiconductor pattern 140 and the source electrode 150s and the drain electrode 150d. In some embodiments, the ohmic contact layer 141 may be formed of n-+ a-Si.

In some embodiments, the semiconductor pattern 140 may be formed of an oxide semiconductor. Examples of the oxide semiconductor may include oxide of a material selected from Groups 12, 13, and 14 metal elements, such as zinc (Zn), indium (In), calcium (Ca), cadmium (Cd), germanium (Ge), hafnium (Hf), or a combination thereof. In some embodiments, the semiconductor pattern 140 may be formed of a Zn oxide-based material (for example, Zn oxide, In—Zn oxide, or Ga—In—Zn oxide). In some embodiments, the semiconductor pattern 140 may be an In—Ga—Zn—O (IGZO) semiconductor containing a metal such as In and Ga in ZnO.

In some alternative embodiments, when the semiconductor pattern 140 is an oxide semiconductor, the ohmic contact layer 141 may be omitted. As such, the ohmic contact layer 141 may be selectively applied depending on the material type of the semiconductor pattern 140.

The source electrode 150s and the drain electrode 150d are disposed on the semiconductor pattern 140 and are spaced apart from each other. The source electrode 150s and the drain electrode 150d may be formed of a same material and may be formed simultaneously. The source electrode 150s and the drain electrode 150d may be formed of Al, Mo, Ti, or Cu. In some embodiments, the source electrode 150s and the drain electrode 150d may have a stack structure comprising Ti/Cu, Mo/Al/Mo, or Ti/Al/Ti. In some embodiments, the source electrode 150s and the drain electrode 150d may have a thickness equal to or greater than about 3000 Å. For example, the source electrode 150s and the drain electrode 150d may have a thickness ranging from about 7000 Å to about 10000 Å.

In some embodiments, the hard mask pattern 160 may be formed on the source electrode 150s and the drain electrode 150d. The hard mask pattern 160 reduces the portions of the source electrode 150s and the drain electrode 150d that are exposed to subsequent processing (e.g. etching). Accordingly, the hard mask pattern 160 can protect the thin film transistor TFT from damage during subsequent processing. Accordingly, although thickness of the source electrode 150s and drain electrode 150d are increased, the thin film transistor TFT may be protected from damage during subsequent processing.

The hard mask pattern 160 may be formed on the source electrode 150s and the drain electrode 150d. The hard mask pattern 160 can prevent the thin film transistor TFT from being contaminated during subsequent processing, as described later in the specification.

The hard mask pattern 160 may have the same area as the top surfaces of the source electrode 150s and the drain electrode 150d. The hard mask pattern 160 may be formed of an insulating material. In some embodiments, the hard mask pattern 160 may include metal oxide such as silicon nitride SiNx, silicon oxide SiOx, and/or AlOx. In some embodiments, the hard mask pattern 160 may have a thickness ranging from about 200 Å to about 2000 Å.

The hard mask pattern 160 may include at least one of a source contact hole H2 exposing the source electrode 150s and a drain contact hole H3 exposing the drain electrode 150d.

The hard mask pattern 160 may be formed including a plurality of layers. In some embodiments, the hard mask pattern 160 may have a stack structure comprising SiNx/SiOx.

A protection layer 170 may be disposed covering the thin film transistor TFT and the data line 123. The protection layer 170 may serve to protect the thin film transistor TFT and/or the data line 123. The protection layer 170 may be formed of an inorganic material such as silicon oxide, silicon nitride, or metal oxide. In some alternative embodiments, the protection layer 170 may be omitted.

The planarization layer 180 may be disposed on the thin film transistor TFT and the data line 123. The planarization layer 180 may be formed as an insulator. The planarization layer 180 may be formed in a single-layer structure or a stack structure comprising an inorganic material, an organic material, or an organic/inorganic composite. In some embodiments, the planarization layer 180 may be formed of an organic material. To reduce parasitic capacitance, a thickness of a planarization layer 180 formed of an organic material may be greater than a thickness of a planarization layer 180 formed of an inorganic material. In some embodiments, the planarization layer 180 may have a planar surface and a thickness ranging from about 3 μm to about 5 μm. The planarization layer 180 may be formed by coating the substrate 110 with a material such as polyacrylate, polyimides, or benzocyclobutene (BCB).

The pixel electrode 190 and the connection wiring 191 may be disposed on the planarization layer 180. The source electrode 150s may be electrically connected to the data line 123 through the connection contact hole H1, the source contact hole H2, and the connection wiring 191. The drain electrode 150d may be electrically connected to the pixel electrode 190 through the drain contact hole H3.

The pixel electrode 190 and the connection wiring 191 may be formed of a same material and may be formed simultaneously. The pixel electrode 190 may be provided as a transparent electrode or a reflective electrode. When the pixel electrode 190 is provided as a transparent electrode, the pixel electrode 190 may be formed of ITO, IZO, ZnO, or In₂O₃. When the pixel electrode 190 is provided as a reflective electrode, the pixel electrode 190 may include a reflective layer formed of Ag, Mg, Al, Pt, PD, Au, Ni, Nd, Ir, Cr, or a compound thereof, and a transparent layer formed of ITO, IZO, ZnO, or In₂O₃. In some embodiments, the pixel electrode 190 and the connection wiring 191 may have an ITO/Ag/ITO structure.

A channel is formed in the semiconductor pattern 140 and a gate signal may be transmitted to the gate electrode 121. The thin film transistor TFT may apply a data voltage transmitted from the data line 123 to the pixel electrode 190 through the source electrode 150s and the drain electrode 150d. The brightness of a pixel may be adjusted by supplying a voltage to an organic emission apparatus or a liquid layer that is disposed on the pixel electrode 190.

FIG. 2 is a cross-sectional view of a thin film transistor array substrate 20 according to another embodiment of the inventive concept. Like reference numerals in the drawings denote like elements in FIGS. 1 and 2, and thus a repeated description of those same elements shall be omitted.

The thin film transistor array substrate 20 of FIG. 2 is similar to the thin film transistor array substrate 10 of FIG. 1 except for the following difference. Specifically, the hard mask pattern 160 of the thin film transistor array substrate 20 has a multilayer structure whereas the hard mask pattern 160 of the thin film transistor array substrate 10 has a single layer structure.

Referring to FIG. 2, the hard mask pattern 160 has a stack structure comprising a first hard mask pattern 161 and a second hard mask pattern 163. The first hard mask pattern 161 and the second hard mask pattern 163 may have the same area as the top surfaces of the source electrode 150s and the drain electrode 150d. The first hard mask pattern 161 and the second hard mask pattern 163 may be formed of an insulating material. In some embodiments, the first hard mask pattern 161 and the second hard mask pattern 163 may include at least one of silicon oxide, silicon nitride, and metal oxide.

In some embodiments, the first hard mask pattern 161 may include silicon nitride SiNx, and the second hard mask pattern 163 may include silicon oxide SiOx.

In the embodiment of FIG. 2, the hard mask pattern 160 has a double layer structure. However, the inventive concept is not limited thereto. For example, in some other embodiments, the hard mask pattern 160 may have a stack structure comprising three or more layers.

In manufacturing the thin film transistor array substrate 20, the thin film transistor TFT may be protected from damage during subsequent processing using the hard mask pattern 160, as described later in the specification.

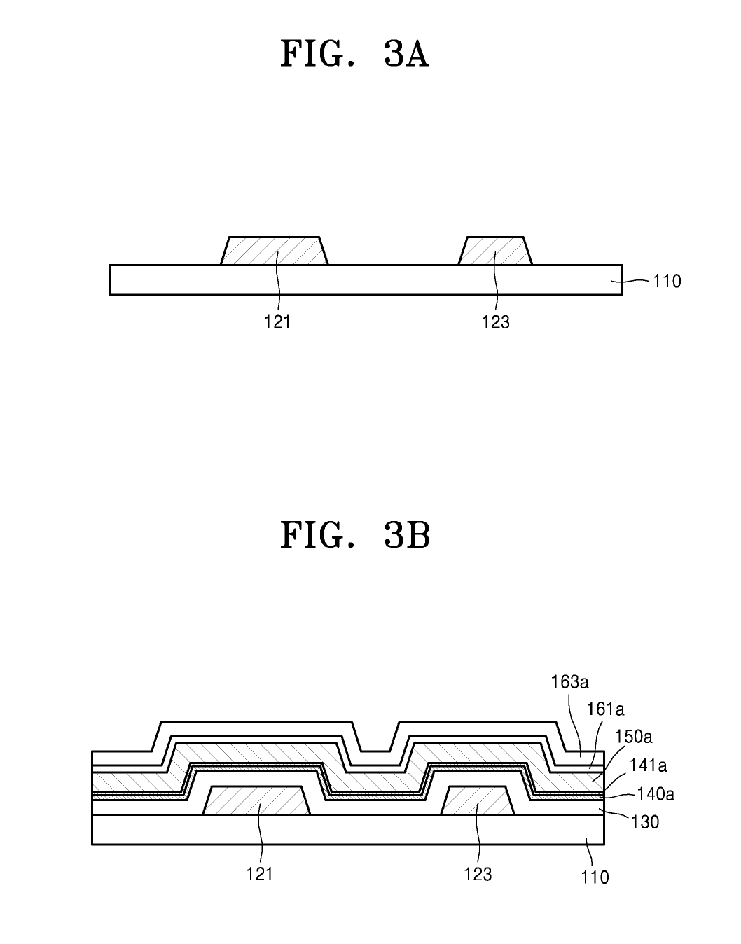

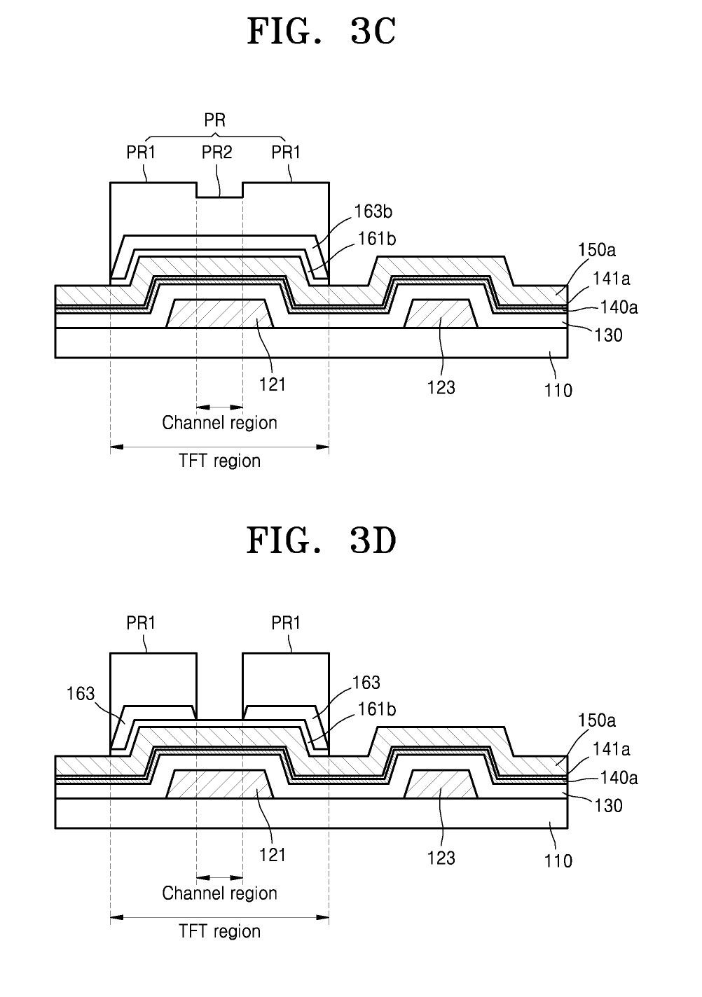

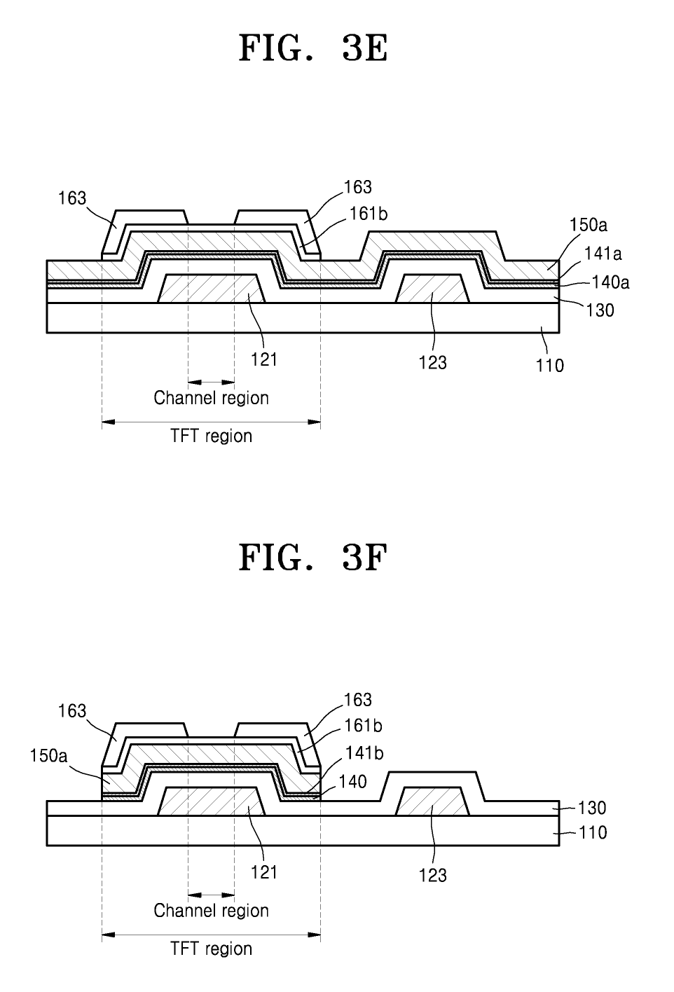

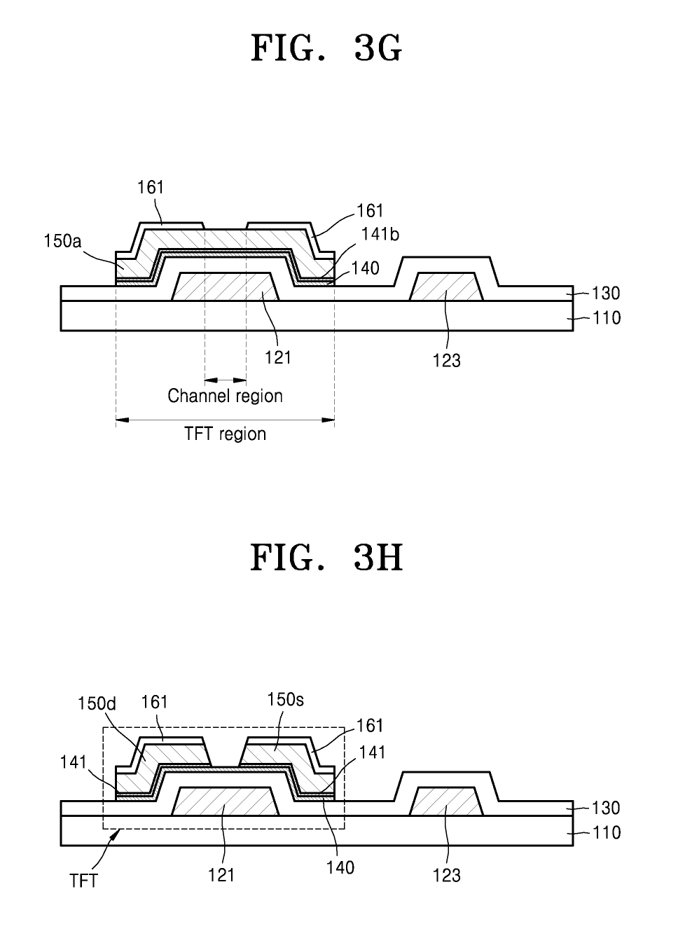

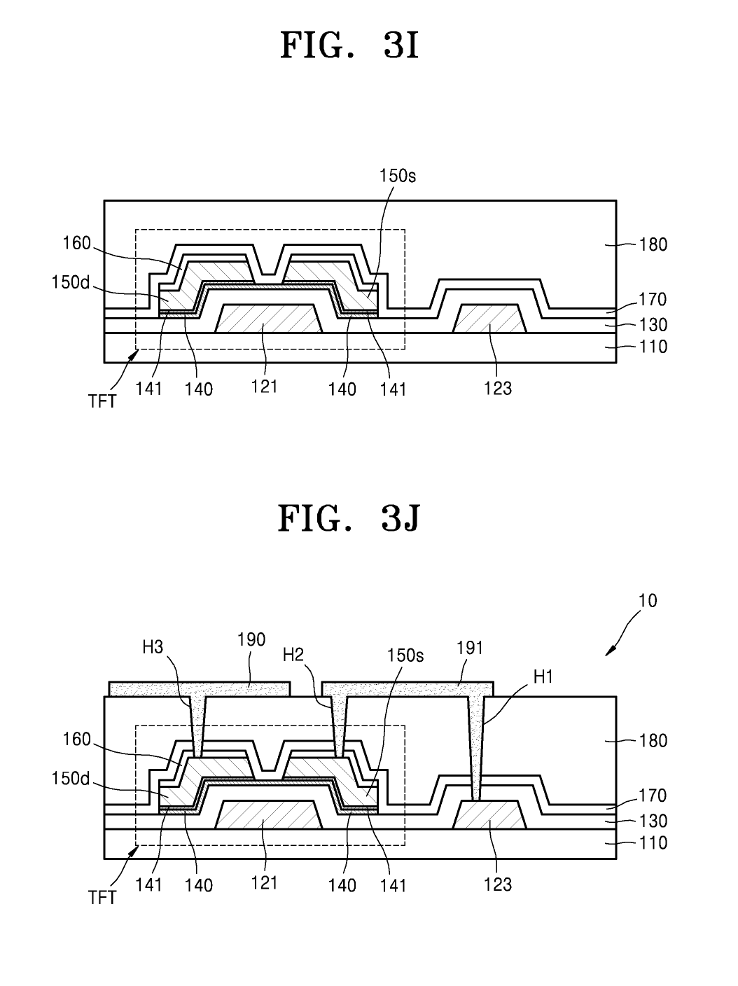

FIGS. 3A through 3I are cross-sectional views sequentially illustrating a thin film transistor array substrate at different stages of fabrication according to an exemplary method of manufacturing the thin film transistor array substrate. Specifically, an exemplary method of manufacturing the thin film transistor array substrate 10 of FIG. 1 will be described with reference to FIGS. 3A through 3I.

Referring to FIG. 3A, the gate electrode 121 and the data line 123 are formed on the substrate 110.

The gate electrode 121 and the data line 123 may be formed by depositing a first conductive layer (not shown) on a surface of the substrate 110 and selectively etching the first conductive layer through photolithography using a first mask. The selective etching may include wet etching, dry etching, or a combination thereof.

The first conductive layer may be formed of aluminum (Al), an aluminum alloy, tungsten (W), copper (Cu), nickel (Ni), chromium (Cr), molybdenum (Mo), titanium (Ti), platinum (Pt), tantalum (Ta), or a combination thereof. In some embodiments, the first conductive layer may be formed of a transparent conductive material such as ITO or IZO. In some embodiments, the first conductive layer may have a stack structure comprising Ti/Cu, Mo/Al/Mo, or Ti/Al/Ti.

The gate electrode 121 and the data line 123 may be formed simultaneously by etching the first conductive layer.

Referring to FIG. 3B, the gate insulating layer 130, a first semiconductor layer 140a, a second semiconductor layer 141a, a source-drain layer 150a, a first hard mask layer 161a, and a second hard mask layer 163a are sequentially formed over the substrate 110 covering the gate electrode 121 and the data line 123. In some alternative embodiments, the second semiconductor layer 14a may be omitted.

The gate insulating layer 130 may be formed of an inorganic or organic insulator. In some embodiments, the gate insulating layer 130 may be formed of metal oxide such as silicon nitride SiNx, silicon oxide SiOx, and/or aluminum oxide AlOx. The gate insulating layer 130 may have a single layer structure or a multilayer structure.

The first semiconductor layer 140a may be formed of amorphous silicon (a-Si) or an oxide semiconductor. When the first semiconductor layer 140a is formed of an oxide semiconductor, the first semiconductor layer 140a may include oxide of a material selected from Groups 12, 13, and 14 metal elements, such as zinc (Zn), indium (In), calcium (Ca), cadmium (Cd), germanium (Ge), hafnium (Hf), or a combination thereof. In some embodiments, the first semiconductor layer 140a may be formed of a Zn oxide-based material (for example, Zn oxide, In—Zn oxide, or Ga—In—Zn oxide). In some embodiments, the first semiconductor layer 140a may be an In—Ga—Zn—O (IGZO) semiconductor containing a metal such as In and Ga in ZnO.

The second semiconductor layer 141a may be formed by doping amorphous silicon with impurities. In some embodiments, the second semiconductor layer 141a may be n+ amorphous silicon doped with a Group V element. In some alternative embodiments, when the second semiconductor layer 141a is an oxide semiconductor, the second semiconductor layer 141a may be omitted.

The source-drain layer 150a may be formed of aluminum (Al), an aluminum alloy, tungsten (W), copper (Cu), nickel (Ni), chromium (Cr), molybdenum (Mo), titanium (Ti), platinum (Pt), tantalum (Ta), or a combination thereof. In some embodiments, the source-drain layer 150a may be formed in a stack structure comprising Ti/Cu, Mo/Al/Mo, or Ti/Al/Ti. The source-drain layer 150a may have a thickness equal to or greater than about 3000 Å. For example, the source-drain layer 150a may have a thickness ranging from about 7000 Å to about 10000 Å.

The first hard mask layer 161a and the second hard mask layer 163a may be formed of an organic or inorganic insulating material. In some embodiments, the first hard mask layer 161a and the second hard mask layer 163a may be formed of an oxide such as silicon nitride SiNx, silicon oxide SiOx, and/or aluminum oxide AlOx. In some embodiments, the first hard mask layer 161a may be formed of silicon nitride SiNx, and the second hard mask layer 163a may be formed of silicon oxide SiOx.

The first hard mask layer 161a and the second hard mask layer 163a may have a same thickness or different thicknesses.

The gate insulating layer 130, the first semiconductor layer 140a, the second semiconductor layer 141a, the source-drain layer 150a, the first hard mask layer 161a, and the second hard mask layer 163a may be formed using various deposition methods such as sputtering, chemical vapor deposition (CVD), plasma enhanced chemical vapor deposition (PECVD), etc.

Referring to FIG. 3C, a photoresist PR including a first part PR1 and a second part PR2 is formed on a TFT region. The TFT region corresponds to a region in which the thin film transistor TFT is to be formed. Specifically, the first part PR1 may be formed in a region in which the source electrode 150s and the drain electrode 150d are to be formed. The second part PR2 may be formed in a channel region of the thin film transistor TFT.

The photoresist PR may be formed using a halftone mask. Therefore, the first and second parts PR1 and PR2 of the photoresist PR may have different thicknesses. For example, a thickness of the second part PR2 may be less than a thickness of the first part PR1.

Next, a preliminary first hard mask pattern 161b and a preliminary second hard mask pattern 163b are formed by etching the portions of the first hard mask layer 161a and the second hard mask layer 163a that are not masked by the photoresist PR. The etching may include wet etching, dry etching, or a combination thereof. In some particular embodiments, the first hard mask layer 161a and the second hard mask layer 163a may be dry etched.

Next, referring to FIG. 3D, the second part PR2 of the photoresist PR is removed through an etch-back process, thereby exposing the portion of the preliminary second hard mask pattern 163b in the channel region. Subsequently, the portion of the preliminary first hard mask pattern 161b in the channel region is exposed by etching the exposed portion of the preliminary second hard mask pattern 163b.

Next, referring to FIG. 3E, the first part PR1 of the remaining photoresist PR is removed through a photoresist stripping process. In particular, a material in the source-drain layer 150a may be eluted by a stripper used in the photoresist stripping process. In the present embodiment, the photoresistor PR is removed in advance to prevent a region (in which the thin film transistor TFT is to be formed) from being contaminated by the material eluted during the photoresist stripping process. Since the photoresistor PR has been removed in advance, the second hard mask pattern 163 and the preliminary first hard mask pattern 161b are then used as etching masks. Accordingly, although thickness of the source electrode 150s and drain electrode 150d are increased, the thin film transistor TFT may be protected from damage during subsequent processing. An increase in the thickness of the source-drain layer 150a may also enable low resistance wirings on the thin film transistor array substrates 10 and 20.

Next, referring to FIG. 3F, the source-drain layer 150a may be etched using the second hard mask pattern 163 as the etching mask. The etching may include wet etching, dry etching, or a combination thereof. In some embodiments, the source-drain layer 150a may be wet etched. Since a channel region of the thin film transistor TFT is not etched, the first semiconductor layer 140a and/or the second semiconductor layer 141a in the channel region of the thin film transistor TFT may be protected from damage during the etching process.

Next, a preliminary ohmic contact layer 141b and the semiconductor pattern 140 are formed by etching the second semiconductor layer 141a and the first semiconductor layer 140a using the second hard mask pattern 163 as the etching mask. The etching may include wet etching, dry etching, or a combination thereof. In some embodiments, the second semiconductor layer 141a and the first semiconductor layer 140a may be dry etched.

Next, referring to FIGS. 3F and 3G, the first hard mask pattern 161 (through which the channel region of the source-drain layer 150a is exposed) is formed by etching the preliminary first hard mask pattern 161b using the second hard mask pattern 163 as the etching mask. The etching may include wet etching, dry etching, or a combination thereof. In some embodiments, the preliminary first hard mask pattern 161b may be dry etched.

Next, the second hard mask pattern 163 may be removed using dry etching. In some alternative embodiments, the second hard mask pattern 163 need not be removed. Accordingly, in those alternative embodiments, the process of removing the second hard mask pattern 163 may be omitted.

Next, referring to FIG. 3H, the source electrode 150s and the drain electrode 150d are formed by etching the source-drain layer 150a using the first hard mask pattern 161 as the etching mask. The etching may include wet etching, dry etching, or a combination thereof. In some embodiments, the source-drain layer 150a may be wet etched.

The ohmic contact layer 141 is formed by selectively removing the exposed preliminary ohmic contact layer 141b. The thin film transistor TFT can be formed using the above-described processes. A de-ionized (DI)-water cleaning and drying process may be carried out after forming the thin film transistor TFT.

Next, referring to FIG. 3I, the protection layer 170 is formed over the substrate 110 covering the thin film transistor TFT and the data line 123. The protection layer 170 may be formed of an inorganic material such as silicon oxide, silicon nitride, or metal oxide. In some alternative embodiments, the protection layer 170 may be omitted. The protection layer 170 may be formed using various deposition methods such as sputtering, CVD, PECVD, etc.

Next, the planarization layer 180 is formed over the substrate 110. The planarization layer 180 may include an insulator. The planarization layer 180 may be formed in a single-layer structure or a stack structure comprising an inorganic material, an organic material, or an organic/inorganic composite. In some embodiments, the planarization layer 180 may be formed of an organic material. In those embodiments, the planarization layer 180 may be formed by coating the substrate 110 with a material such as polyacrylate, polyimides, or benzocyclobutene (BCB) and curing the material.

Next, referring to FIG. 3J, the source contact hole H2 and the drain contact hole H3 are formed passing through the planarization layer 180, the protection layer 170, and the first hard mask pattern 161. Similarly, the connection contact hole H1 is formed passing through the planarization layer 180, the protection layer 170, and the gate insulating layer 130. The connection contact hole H1 extends to the data line 123, the source contact hole H2 extends to the source electrode 150s, and the drain contact hole H3 extends to the drain electrode 150d.

Next, the pixel electrode 190 and the connection wiring 191 are formed on the planarization layer 180. The pixel electrode 190 and the connection wiring 191 may be formed by depositing and patterning a second conductive layer (not shown). The pixel electrode 190 may be electrically connected to the drain electrode 150d by filling the drain contact hole H3. The connection wiring 191 fills the source contact hole H2 and the connection contact hole H1, and serves to electrically connect the source electrode 150s and the data line 123.

The pixel electrode 190 and the connection wiring 191 may be formed of a same material and may be formed simultaneously. The pixel electrode 190 may be provided as a transparent electrode or a reflective electrode. When the pixel electrode 190 is provided as a transparent electrode, the pixel electrode 190 may be formed of ITO, IZO, ZnO, or In₂O₃. When the pixel electrode 190 is provided as a reflective electrode, the pixel electrode 190 may include a reflective layer formed of Ag, Mg, Al, Pt, PD, Au, Ni, Nd, Ir, Cr, or a compound thereof, and a transparent layer formed of ITO, IZO, ZnO, or In₂O₃. In some embodiments, the pixel electrode 190 and the connection wiring 191 may have an ITO/Ag/ITO structure.

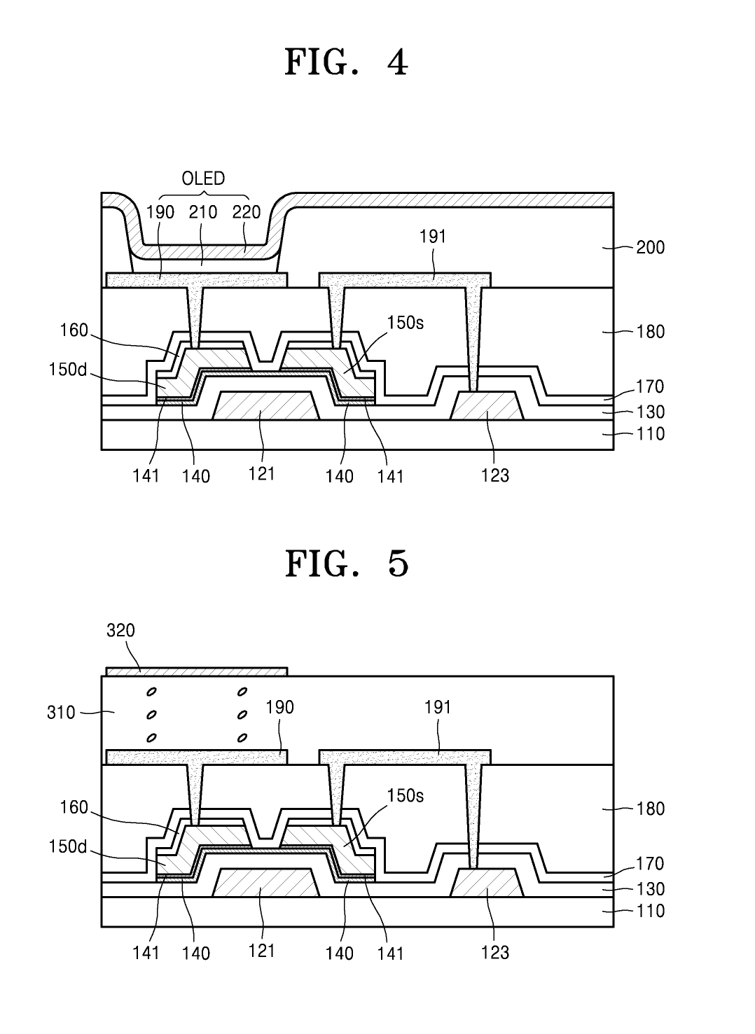

FIG. 4 is a cross-sectional view of an organic light emitting display apparatus including the thin film transistor array substrate 10 of FIG. 1. Like reference numerals in the drawings denote like elements in FIGS. 1 and 4, and thus a repeated description of those same elements will be omitted.

The thin film transistor array substrate of FIG. 4 includes a pixel defining layer 200, an intermediate layer 210 including an organic emission layer, and an opposite electrode 220. The pixel defining layer 200, the intermediate layer 210, and the opposite electrode 220 may be formed on the thin film transistor array substrate 10 of FIG. 1.

The pixel defining layer 200 may define a pixel region and a non-pixel region. The pixel defining layer 200 may include an opening 200a formed in the pixel region, and may be formed covering the substrate 110. The intermediate layer 210 may be formed in the opening 200a. Accordingly, the opening 200a may be disposed corresponding to the pixel region.

The pixel electrode 190, the intermediate layer 210, and the opposite electrode 220 constitute the key elements of an organic light-emitting apparatus. Specifically, holes and electrons injected from the pixel electrode 190 and the opposite electrode 220 of the organic light-emitting apparatus may be combined in the organic emission layer (of the intermediate layer 210) to emit light.

As described above, the intermediate layer 210 may include the organic emission layer. Alternatively, in another embodiment, the intermediate layer 210 may include the organic emission layer and at least one of a hole injection layer (HIL), a hole transport layer (HTL), an electron transport layer (ETL), and an electron injection layer (EIL). However, the inventive concept is not limited thereto. For example, in some other embodiments, the intermediate layer 210 may further include other types of functional layers in addition to the organic emission layer.

The opposite electrode 220 is formed on the intermediate layer 210. The opposite electrode 220 and the pixel electrode 190 generate an electric field, thereby emitting light from the intermediate layer 210. The pixel electrode 190 may be patterned for each pixel, and the opposite electrode 220 may be formed to allow a common voltage to be applied to all the pixels.

The pixel electrode 190 and the opposite electrode 220 may be provided as a transparent electrode or a reflective electrode. In one embodiment, the pixel electrode 190 may serve as an anode electrode, and the opposite electrode 220 may serve as a cathode electrode. However, the inventive concept is not limited thereto. For example, in another embodiment, the pixel electrode 190 may serve as the cathode electrode, and the opposite electrode 220 may serve as the anode electrode.

Although only one organic light-emitting apparatus is illustrated in FIG. 4, it should be appreciated that a display panel may include a plurality of organic light-emitting apparatuses. Each organic light-emitting apparatus OLED may include a pixel, and each pixel may display a red, green, blue, or white color.

In some embodiments, the intermediate layer 210 may be formed over the entire pixel electrode 190 regardless of the position of each pixel. For example, the organic emission layer may be formed by vertically stacking or combining a plurality of layers including light-emitting materials that respectively emit red, green, and blue light. Also, if the organic emission layer emits white light, a combination of the red, green, and blue colors and the white color may be obtained. In some embodiments, the organic light-emitting display apparatus may further include a color filter or a color conversion layer for converting the emitted white light to light of a particular color.

A protection layer (not shown) may be disposed on the opposite electrode 220 covering the organic light-emitting apparatus. The protection layer may include an inorganic insulating layer and/or an organic insulating layer.

FIG. 5 is a cross-sectional view of a liquid crystal display (LCD) apparatus including the thin film transistor array substrate 10 of FIG. 1. Like reference numerals in the drawings denote like elements in FIGS. 1 and 5, and thus a repeated description of those same elements will be omitted.

The thin film transistor array substrate of FIG. 5 includes an intermediate layer 310 including a liquid crystal, an opposite electrode 320, and a color filter layer (not shown). The intermediate layer 310, the opposite electrode 320, and the color filter layer may be formed on the thin film transistor array substrate 10 of FIG. 1.

As described above, the intermediate layer 310 may include the liquid crystal. An alignment of the liquid crystal in the intermediate layer 310 may be changed according to an electric field generated between the pixel electrode 190 and the opposite electrode 320. Accordingly, transmittance of light passing through the intermediate layer 310 may be modulated according to the alignment of the liquid crystal in the intermediate layer 310.

The opposite electrode 320 is formed on the intermediate layer 310. The opposite electrode 320 may be formed so that a common voltage can be applied to each pixel. The opposite electrode 320 may be formed in various shapes. For example, in some embodiments, the opposite electrode 320 may include a plurality of slits.

A color filter layer (not shown) may be further formed on the opposite electrode 320. The color filter layer may include a red, green, or blue filter depending on the color of the pixels. A backlight unit (not shown) disposed under the thin film transistor array substrate 10 may be configured to emit light. The color filter layer may apply a color to the emitted light after the emitted light has passed through the intermediate layer 310.

Although only one pixel is illustrated in FIG. 5, it should be appreciated that a display panel may include a plurality of pixels.

The thin film transistor array substrates 10 and 20 according to the embodiments of the inventive concept may be used in organic light-emitting display apparatuses or LCD apparatuses. However, the inventive concept is not limited thereto. For example, one of ordinary skill in the art would appreciate that the thin film transistor array substrates 10 and 20 may be used in other types of display apparatuses such as plasma display apparatuses and electrophoretic display apparatuses.

According to one or more of the above embodiments of the inventive concept, a hard mask pattern of a thin film transistor array substrate is disposed on a source electrode and a drain electrode. The hard mask pattern reduces the portions of the source electrode and the drain electrode that are exposed to subsequent processing. Accordingly, the hard mask pattern can protect the thin film transistor from damage during subsequent processing.

It should be understood that the embodiments described herein are merely exemplary and should not be construed as limiting the inventive concept.

While one or more embodiments of the inventive concept have been described with reference to the figures, it will be understood by those of ordinary skill in the art that various changes may be made to the embodiments without departing from the spirit and scope of the present disclosure.

What is claimed is:

1. A thin film transistor array substrate comprising:
a substrate:
a gate electrode disposed on the substrate;
a gate insulating layer disposed on the gate electrode;
a semiconductor pattern disposed on the gate insulating layer;
a source electrode and a drain electrode disposed on the semiconductor pattern and spaced apart from each other; and
a hard mask pattern disposed on the source electrode and the drain electrode.

2. The thin film transistor array substrate of claim 1, wherein the hard mask pattern has a same area as a top surface of the source electrode and a top surface of the drain electrode.

3. The thin film transistor array substrate of claim 1, wherein the hard mask pattern is formed of an insulating material.

4. The thin film transistor array substrate of claim 1, wherein the hard mask pattern has a stack structure comprising a first hard mask pattern and a second hard mask pattern, and wherein the first hard mask pattern and the second hard mask pattern are formed of different materials.

5. The thin film transistor array substrate of claim 1, wherein the hard mask pattern comprises a contact hole exposing at least one of the source electrode and the drain electrode.

6. The thin film transistor array substrate of claim 1, further comprising:
an ohmic contact layer disposed between the semiconductor pattern and the source electrode and between the semiconductor layer and the drain electrode,
wherein the semiconductor pattern comprises amorphous silicon (a-Si).

7. The thin film transistor array substrate of claim 1, wherein the semiconductor pattern comprises an oxide semiconductor.

8. The thin film transistor array substrate of claim 1, further comprising:
a data line disposed on the substrate and spaced apart from the gate electrode,
wherein the gate insulating layer is disposed covering the data line, and
wherein the data line is electrically connected to the drain electrode.

9. The thin film transistor array substrate of claim 1, further comprising:
a protection layer covering the hard mask pattern, the source electrode, the semiconductor pattern, and the drain electrode.

10. The thin film transistor array substrate of claim 1, further comprising:
a pixel electrode connected to the source electrode; and
a planarization layer disposed between the source electrode and the pixel electrode.

11. The thin film transistor array substrate of claim 10, wherein the planarization layer comprises an organic material.

12. The thin film transistor array substrate of claim 10, further comprising:
an intermediate layer disposed on the pixel electrode, wherein the intermediate layer comprises an organic emission layer or a liquid crystal layer; and
an opposite electrode disposed on the intermediate layer.

13. A method of manufacturing a thin film transistor array substrate, comprising:
forming a gate electrode and a data line on a substrate, wherein the substrate comprises a thin film transistor region;
sequentially forming a gate insulating layer, a semiconductor pattern comprising a channel region, and a source-drain layer on the substrate covering the gate electrode and the data line;
forming a preliminary first hard mask pattern on the source-drain layer in the thin film transistor region;
forming a second hard mask pattern on the preliminary first hard mask pattern, wherein the second hard mask pattern includes a second opening disposed corresponding to the channel region;
etching the source-drain layer by using the preliminary first hard mask pattern as a first etching mask;
forming a first hard mask pattern by using the second hard mask pattern as a second etching mask, wherein the first hard mask pattern includes a first opening disposed corresponding to the channel region; and
forming a source electrode and a drain electrode by etching the source-drain layer using the first hard mask pattern as a third etching mask.

14. The method of claim 13, wherein the preliminary first hard mask pattern and the second hard mask pattern are formed through a halftone mask process.

15. The method of claim 13, wherein forming the second hard mask pattern further comprises:
forming a second hard mask layer on the source-drain layer;
forming a photoresist using a halftone mask, wherein the photoresist comprises a first part and a second part, and wherein a thickness of the second part is less than a thickness of the first part;
etching the source-drain layer by using the photoresist as a fourth etching mask;
exposing a portion of the second hard mask layer corresponding to the channel region by etching the second part of the photoresist; and
etching the exposed portion of the second hard mask layer by using the first part of the photoresist as a fifth etching mask,
wherein the first part of the photoresist is formed in a region in which the source electrode and the drain electrode are to be formed, and the second part of the photoresist is disposed corresponding to the channel region.

16. The method of claim 13, wherein the first hard mask pattern and the second hard mask pattern are formed of different insulating materials.

17. The method of claim 13, further comprising:
removing the second hard mask pattern.

18. The method of claim 13, further comprising:
forming a planarization layer over the substrate covering the source electrode, the drain electrode, and the data line.

19. The method of claim 18, further comprising:
forming a pixel electrode and a connection wiring on the planarization layer, wherein the pixel electrode is connected to the source electrode and the connection wiring is connected to the drain electrode.
